(19) United States
(12) Patent Application Publication
(10) Pub. No.: US 2017/0265331 A1
(43) Pub. Date: Sep. 14, 2017

(54) Heat Dissipating Heat Sink Retainer

(71) Applicant: Enzo Technology Corp., Chino, CA (US)

(72) Inventor: Kuo-An Robert Liang, Taoyuan City (TW)

(21) Appl. No.: 15/067,371

(22) Filed: Mar. 11, 2016

(51) Int. Cl. H05K 7/20; F28F 9/007; F28F 3/02

(52) U.S. Cl. CPC H05K 7/20409; F28F 3/02; F28F 9/0075; F28D 2021/0029

(57) ABSTRACT

A retainer for detachably coupling a heat absorbing/dissipating device to a heat source is disclosed. The retainer can include one or more cooling fins to enable the retainer to dissipate heat along with the heat dissipating device. The cooling fins on the retainer can be wedge-shaped or airfoil-shaped, among other things, to increase, direct, and smooth airflow over the retainer, the heat source, and the heat dissipating device. The heat dissipating device can include a heat sink with multiple cooling fins. The cooling fins on the retainer can have substantially the same geometric pattern as the cooling fins on the heat sink.

### BACKGROUND

A retainer is usually implemented to facilitate close attachment of a heat sink onto an IC to provide efficient heat dispersion. This is desirable to keep the IC cool under normal conditions, particularly during high-speed operation. Operating temperatures above a predetermined threshold, for example, can result in logical and electrical malfunctions. Extended operation at high temperature, or operation at extreme temperatures, can cause permanent electrical or mechanical damage and/or failure of the IC.

As the name implies, in the past, heat sink retainers have been use merely to firmly attach the heat sink to the IC. In this manner, while they provide mechanical attachment, due to their limited surface area, they provide little to no additional cooling. Indeed, the retainers can actually reduce the surface area available for use on the heat sink, reducing the heat sink's capacity for heat rejection.

### SUMMARY

Examples of the present disclosure comprise systems and apparatus for retaining a heat dissipating/absorbing device (“heat sink”) on a heat source. In some examples, the heat sink can comprise a first side in contact with the heat source. The heat sink can also comprise a plurality of heat sink cooling fins disposed on the second side of the heat sink designed to dissipate the heat generated by the heat source. In some examples, the heat source can be an integrated circuit (IC) or other electronic or electromechanical device that generates heat in the normal course of operation.

The apparatus can comprise a retainer designed to detachably couple, or clip, the heat sink onto the IC (or other heat source). The retainer can include a plurality of retainer cooling fins designed to work in concert with the heat sink cooling fins to improve the performance of the heat sink/retainer system (“the system”). In some examples, the retainer cooling fins can be disposed in a geometrical pattern that is the same as, or similar to, the geometrical pattern of the heat sink cooling fins. In other examples, the retainer cooling fins can be sized and shaped to direct air around the frame of the retainer or through the heat sink, among other things.

The retainer cooling fins can be shaped to direct, improve, and/or smooth airflow over the system. In some examples, the retainer cooling fins can be substantially wedge-shaped—with the base wider than the tip—to smooth airflow over the frame of the retainer. In other examples, the retainer cooling fins can be substantially airfoil-shaped—such that one side of the retainer cooling fin is longer than the other—to smooth and direct airflow in a particular direction.

The retainer can include one or more alignment pins and or alignment slots to enable the retainer, heat dissipation device, and heat source to be aligned and detachably coupled. The retainer can also include one or more vertical projections, or walls, to further align and/or contain the heat dissipation device and heat source. In some examples, the retainer can also include one or more hold-downs to enable the retainer to exert downward pressure on the heat sink to maintain contact between the heat sink and heat source.

### BRIEF DESCRIPTION OF THE DRAWINGS

The related drawings in connection with the detailed description of this disclosure, which is to be made later, are described briefly as follows, in which:

FIG. 1 is an exploded, isometric view of a heat sink retainer, along with a heat sink, and the top portion of an integrated circuit (IC), in accordance with some examples of the present disclosure.

FIG. 2 is an isometric, top view of the heat sink retainer of FIG. 1, in accordance with some examples of the present disclosure.

FIG. 3 is an isometric, bottom view of the heat sink retainer of FIG. 1, in accordance with some examples of the present disclosure.

FIG. 4 is a top view of the heat sink retainer of FIG. 1, in accordance with some examples of the present disclosure.

FIG. 5 is a bottom view of the heat sink retainer of FIG. 1, in accordance with some examples of the present disclosure.

FIG. 6A is a side view of the heat sink retainer of FIG. 1 with wedge-shaped retainer cooling fins, in accordance with some examples of the present disclosure.

FIG. 6B is a side view of a heat sink retainer with airfoil shaped retainer cooling fins, in accordance with some examples of the present disclosure.

FIG. 7 is another side view of the heat sink retainer of FIG. 1 with wedge-shaped retainer cooling fins, in accordance with some examples of the present disclosure.

FIG. 8 is an isometric view of the heat sink retainer of FIG. 1 installed on the heat sink of FIG. 7, in accordance with some examples of the present disclosure.

FIG. 9 is a top view of the heat sink retainer of FIG. 1 installed on the heat sink of FIG. 7, in accordance with some examples of the present disclosure.

FIG. 10 is a bottom view of the heat sink retainer of FIG. 1 installed on the heat sink of FIG. 7, in accordance with some examples of the present disclosure.

FIG. 11 is a side view of the heat sink retainer of FIG. 1 installed on the heat sink of FIG. 7, in accordance with some examples of the present disclosure.

FIG. 12 is another side view of the heat sink retainer of FIG. 1 installed on the heat sink of FIG. 7, in accordance with some examples of the present disclosure.

### DETAILED DESCRIPTION

Examples of the present disclosure can comprise a system for cooling a heat source, such as an IC. The system can include a retainer for mechanically attaching a heat absorbing/dissipating device (e.g., a heat sink) to a heat source (e.g., an IC). The retainer can include multiple arms and tabs for attachment of the heat sink to the IC. The retainer can also include a plurality of cooling fins to provide additional cooling to the IC and replace the cooling fins on the heat sink that are normally removed to provide attachment locations.

For ease of explanation, the apparatus and system are discussed below with reference to a heat sink and a retainer for use on an IC. One of skill in the art will recognize, however, that in addition to ICs, the system could also be used to cool other electronic, electromechanical, and mechanical heat sources. In addition, while described as a system for use with a finned heat sink, the system could also be used in conjunction with other devices such as, for example, CPU water coolers, radiators, and printed circuit boards.

As mentioned above, a problem with existing heat sink retainers is that they (1) do not provide any additional cooling capacity and (2) actually reduce the cooling capacity of a heat sink. The retainers do not provide any appreciable cooling capacity because they are generally flat metal plates concerned only with attaching the heat sink to the IC, for example. Thus, while they may have clips, alignment pins, arms, or other attachment means, they do not provide significant additional cooling. In addition, in order for the retainer to attach the heat sink to the IC, there are generally no fins on the heat sink in the one or more locations where the retainer interfaces with the heat sink. As a result, the heat sink has fewer fins than would be available otherwise, reducing its cooling capacity.

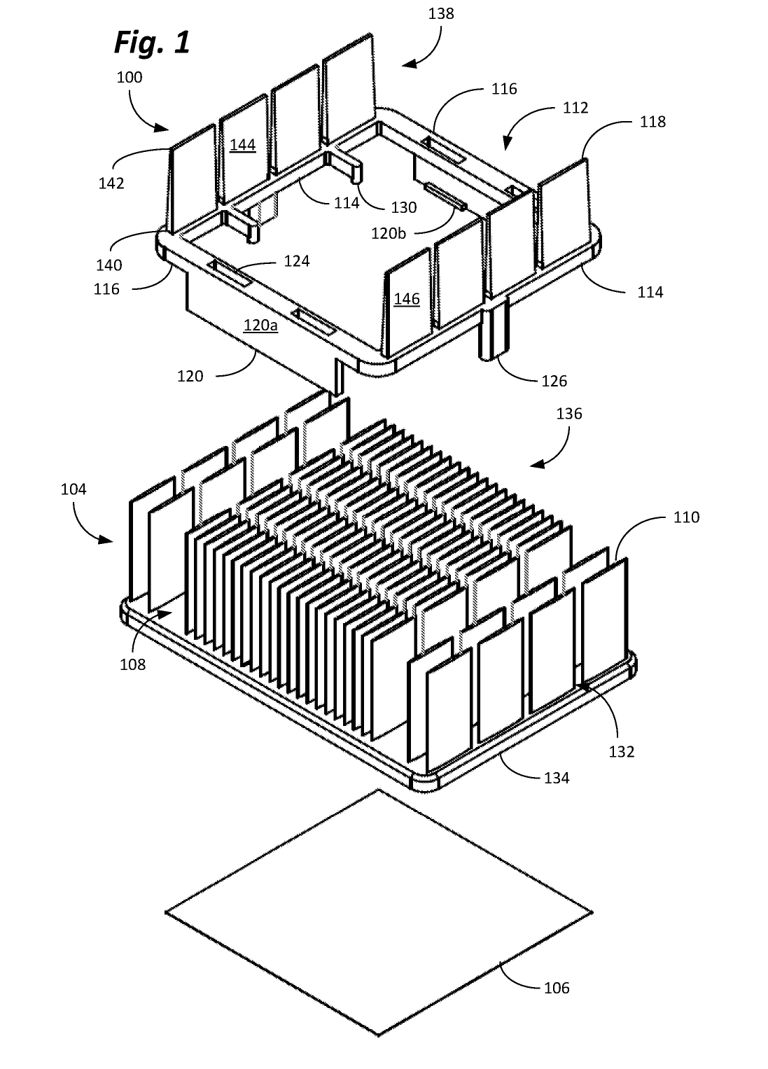

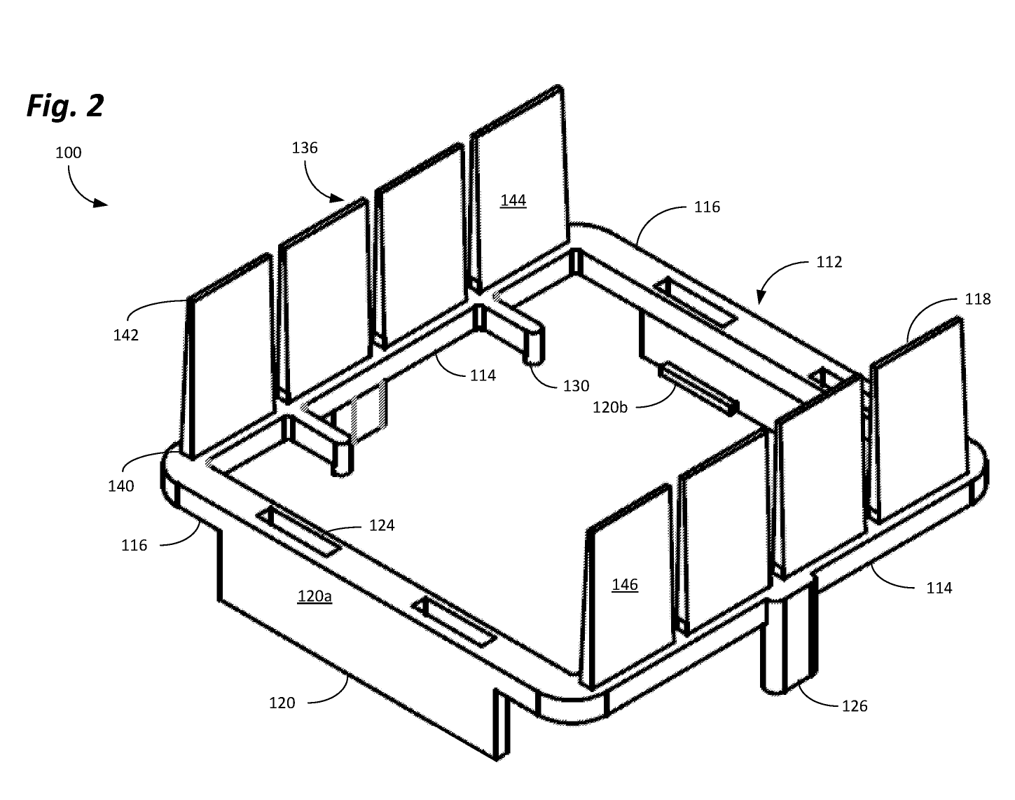

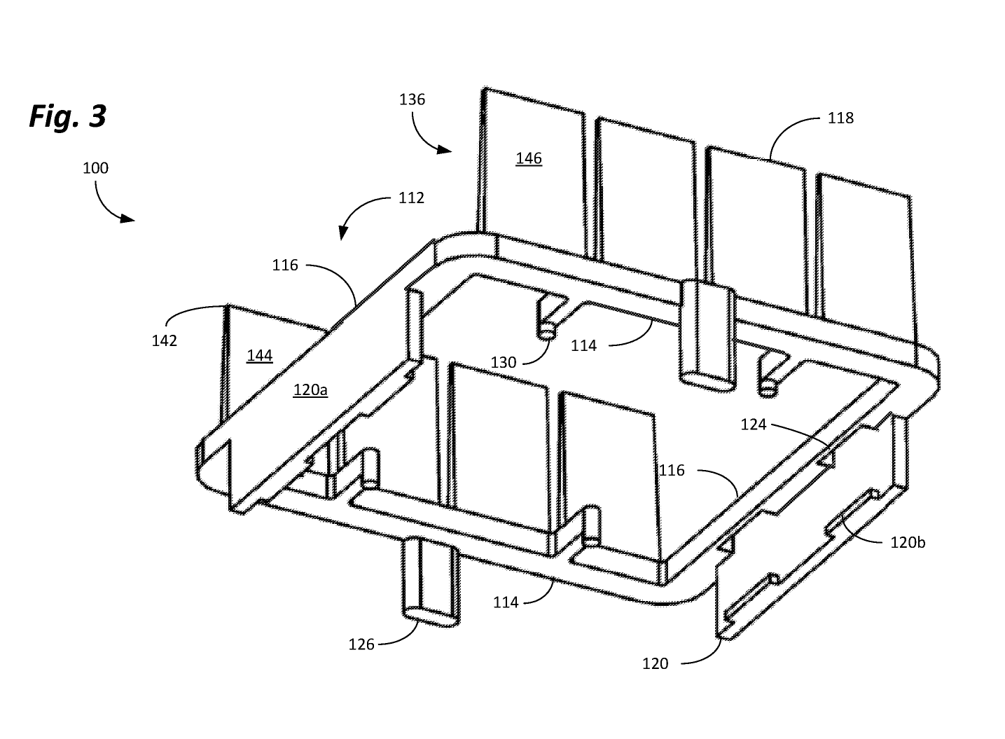

To this end, as shown in FIGS. 1-3, examples of the present disclosure can comprise a retainer 100 that includes a plurality of cooling fins 118. In this manner, the retainer 100 can serve its normal function—i.e., mechanically coupling a heat sink 104 to an IC 106 (or other heat source), while also providing additional cooling capacity to the system. In this manner, the retainer 100 can replace the cooling capacity of the heat sink 104 lost due to the row(s) 108 on the heat sink 104 that have no heat sink cooling fins 110—i.e., the rows 108 lost to enable the retainer 100 to affix the heat sink 104 to the IC 106.

The retainer 100 can comprise a substantially square or rectangular frame 112 sized and shaped to fit a particular heat sink 104. In some examples, the frame 112 can comprise one or more standardized shapes designed to fit standard heat sinks 104. In other examples, the frame 112 can be “custom,” or specific, to each type of heat sink 104. The frame 112 can comprise lateral rails 114 and longitudinal rails 116.

The heat sink 104 can include a plurality of heat sink cooling fins 110. The heat sink cooling fins 110 increase the surface area of the heat sink 104 significantly and enable the heat sink 104 to reject exponentially more heat. In the area of the heat sink 104 where it engages with the retainer 100, however, there are generally one or more rows 108 of heat sink cooling fins 110 missing. This obviously measurably reduces the cooling capacity of the heat sink 104.

Using a conventional, flat retainer, however, does nothing to remedy this loss of cooling capacity. Indeed a conventional retainer is doubly inefficient. In other words, the retainer itself provides little, or no, additional cooling because it simply comprises flat components. In addition, the heat sink 104 has fewer heat sink cooling fins 110 due to the attachment location of the retainer. In some examples, therefore, the retainer 100 disclosed herein can comprise one or more retainer cooling fins 118.

In some examples, as shown, only the lateral rails 114 can include retainer cooling fins 118. This may be useful to match the fin pattern 138 on the retainer 100 to the fin pattern 136 on the heat sink 104, for example, to improve airflow, direct airflow, or to improve the uniformity of airflow over the heat sink 104 and/or IC 106. This may be useful to prevent localized overheating of the heat sink 104 and/or the IC 106, to avoid turbulence, or to direct airflow over and around obstacles, among other things. In other examples, the fin pattern 138 on the retainer 100 can be the same as the fin pattern 136 on the heat sink 104 simply due to packaging, handling, or other requirements. In other examples, the fin patterns 136, 138 can be different to facilitate turbulent flow, for example, or to direct air in a particular direction.

In other examples, the longitudinal rails 116 can also include retainer cooling fins 118 in addition to, or instead of, the lateral rails 114. This may be useful to further increase the cooling capacity of the retainer 100, for example, by further increasing the surface area of the retainer 100. In some examples, this may enable the retainer 100/heat sink 104 system to meet certain cooling requirements for the IC 106. In some examples, space simply may not be at a premium, enabling extra retainer cooling fins 118 to be included on the frame 112 of the retainer 100. In still other examples, the retainer cooling fins 118 located on the longitudinal rails 116 can be disposed perpendicular to the heat sink cooling fins 110 on the lateral rails 114. This may be useful to contain or direct the airflow over the heat sink 104 and/or IC 106. In other words, the retainer cooling fins 118 located on the longitudinal rails 116 and the heat sink cooling fins 110 on the lateral rails 114 can act to “box in” the airflow over the heat sink 104 and IC 106 to improve the volume, velocity, or laminarity of the airflow, among other things.

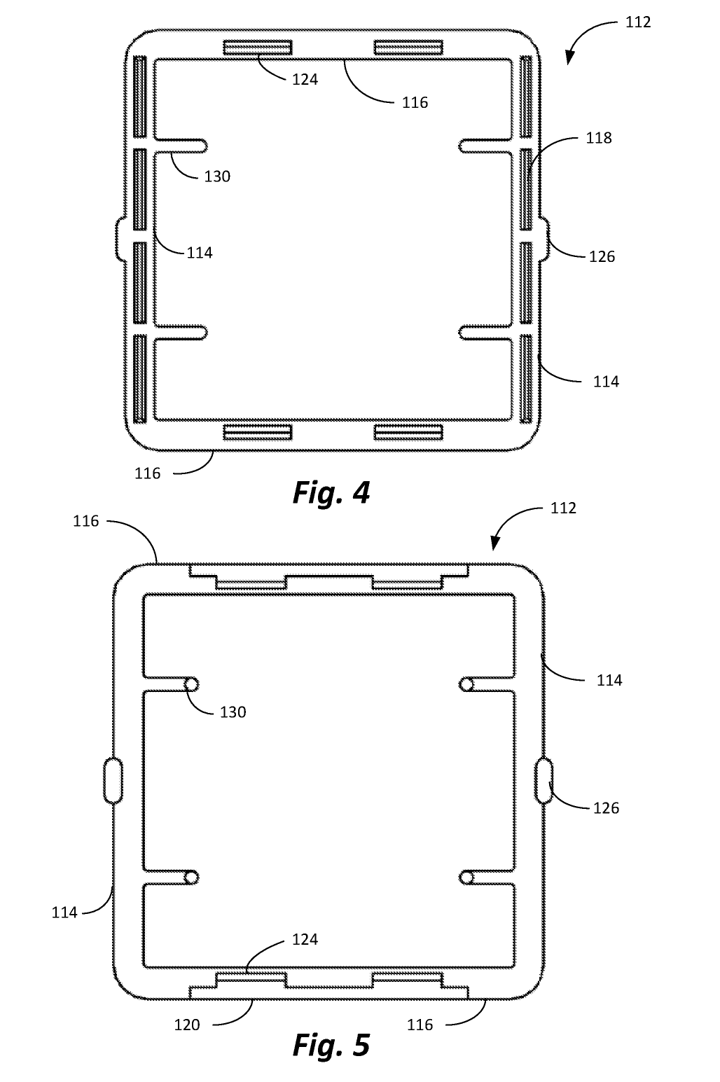

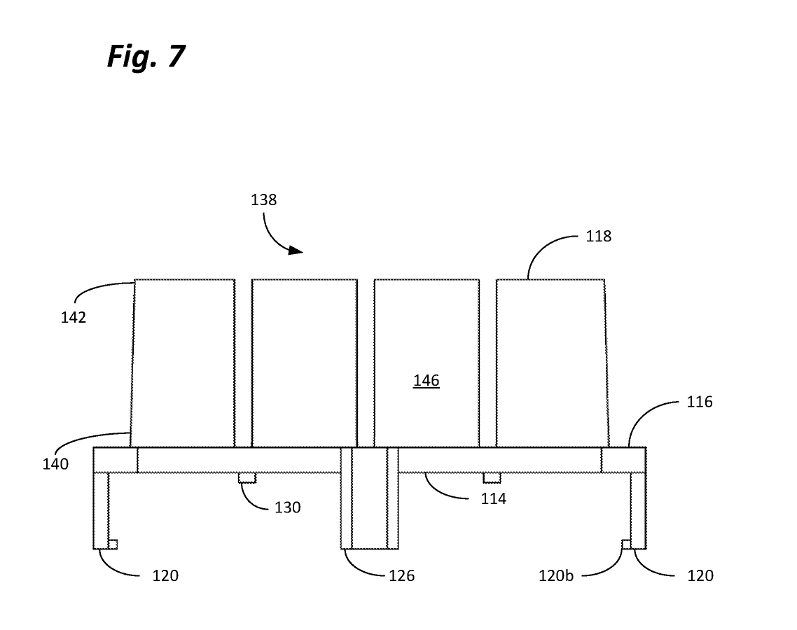

As shown in FIGS. 1-7, the rails can also comprise one or more clips 120 and slots 124 to enable the retainer 100 to engage with a heat sink 104 and/or IC 106. In some examples, the longitudinal rail 116 can include a clip 120 with a relatively long vertical wall 120a to enable the clip 120 to encompass the heat sink 104 and/or IC 106. This can enable the retainer 100 to provide support and alignment to the heat sink 104 and/or IC 106, which can improve thermal conductivity between the components 104, 106, among other things.

In some examples, the clip 120 can also comprise a tab 120b. The tab 120b can be sized and shaped to mechanically affix the heat sink 104 to the IC 106 (or other heat source). In some examples, one or more of the retainer 100, clip 120, vertical wall 120a, or tab 120b can comprise a relatively resilient material (e.g., plastic, spring steel, or aluminum) to enable the vertical wall 120a and/or tab 120b to provide some spring-back. In this method the retainer 100 can simply be placed over the heat sink 104 and IC 106, for example, and be “snapped” into place.

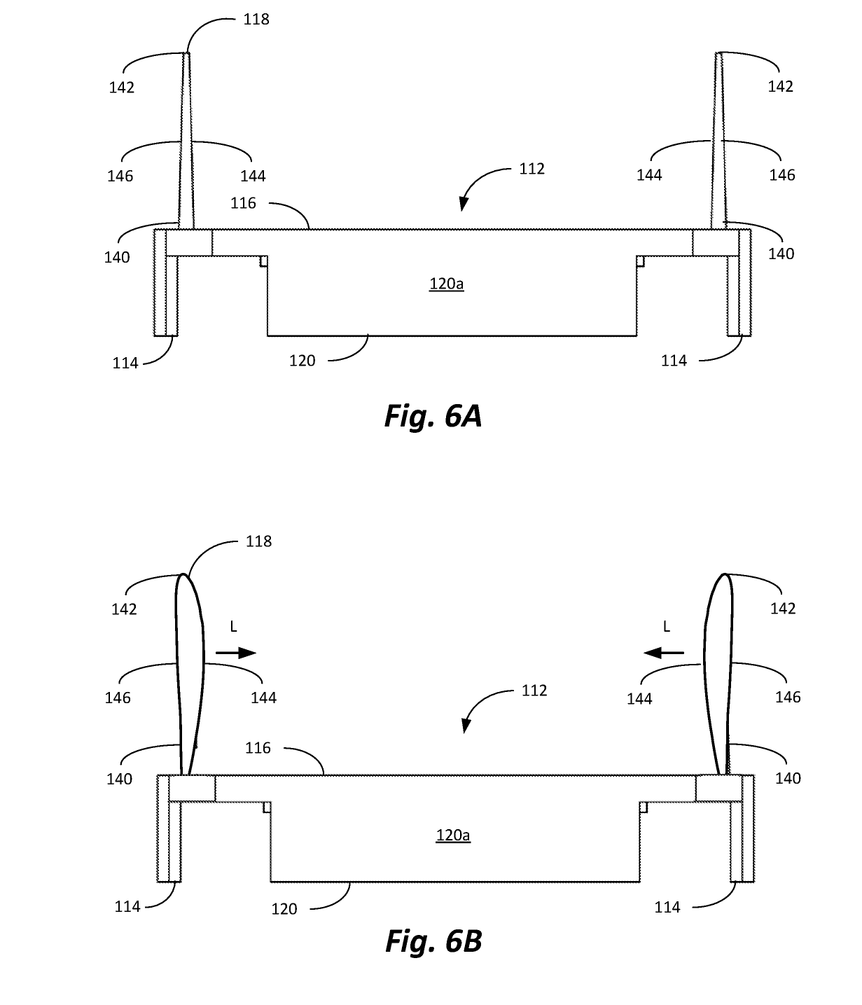

As shown in FIGS. 1 and 6A-6B, in some examples, the lateral rails 114 can also comprise one or more alignment pins 126. The alignment pins 126 can enable the retainer 100 to be aligned with the heat sink 104, the IC 106, and the PCB, or other components or other substrates (not shown) onto which the IC 106 or retainer 100 is being installed. In this manner, like the clip 120, the alignment pins 126 can assist in aligning and containing the components 100, 104, 106 during assembly. This can ease installation and prevent damage, among other things.

In some examples, as shown in FIGS. 1 and 6A, the retainer cooling fins 118 can be substantially wedge-shaped. In other words, the retainer cooling fins 118 can be wider at the base 140 than at the tip 142. In this manner, the retainer cooling fins 118 can substantially direct and smooth air flow over the rails 114, 116 of the retainer 100, or other obstacles. In some examples, the base 140 of the retainer cooling fin 118 can be substantially the same width as the rail 114, 116 on which it is mounted, for example, to smooth the airflow over the rail 114, 116. In this manner, a stagnation point proximate the location where the retainer cooling fin 118 meets the rail 114, 116 can be eliminated.

In other embodiments, as shown in FIG. 6B, the retainer cooling fins 118 can comprise other shapes. The retainer cooling fins 118 can be substantially airfoil shaped, for example, to direct air in a particular direction. In some examples, a top surface 144 of the retainer cooling fin 118 can be longer than a bottom surface 146 of the retainer cooling fin 118. In this manner, as air flows over the retainer cooling fin 118, the retainer cooling fin 118 creates “lift” in one direction or the other—i.e., depending on the orientation of the airfoil.

As shown in FIG. 6B, lift, L, is created in the inward direction, which can direct air towards the inside of the retainer 100. This may be useful to increase airflow over a particular portion of the heat sink 104, for example, to direct air around the frame 112 of the retainer 100, or between the retainer 100 and the heat sink 104. Of course, the opposite is also true and reversing the airfoil on the retainer cooling fin 118 would create lift in an outward direction. As before, this may be useful to increase airflow over a particular portion of the heat sink 104, or to direct air around the frame 112 of the retainer 100, or between the retainer 100 and the heat sink 104, among other things.

In some examples, as shown in FIGS. 1-5, the retainer 100 can also comprise one or more slots 124 and one or more hold downs 130. The slots 124 can be sized and shaped, for example, to interact with one or more tabs or alignment pins on the heat sink 104 or IC 106. This can enable the components 100, 104, 106 to be properly aligned to ease attachment and prevent damage, among other things.

The hold downs 130 can enable the retainer 100 to press the heat sink 104 firmly against the IC 106. By applying even pressure to the heat sink 104, the hold downs 130 can improve thermal conduction between the heat sink 104 and the IC 106 and reduce vibration, among other things. In some examples, the hold downs 130 can be sized and shaped to coincide with the columns 132 of heat sink cooling fins 110 on the heat sink 104. In this manner, the hold downs 130 can apply firm downward pressure to the base 134 of the heat sink 104 without damaging the heat sink cooling fins 110. In some examples, heat sink grease can be applied between the heat sink 104 and the IC 106 to further improve conduction.

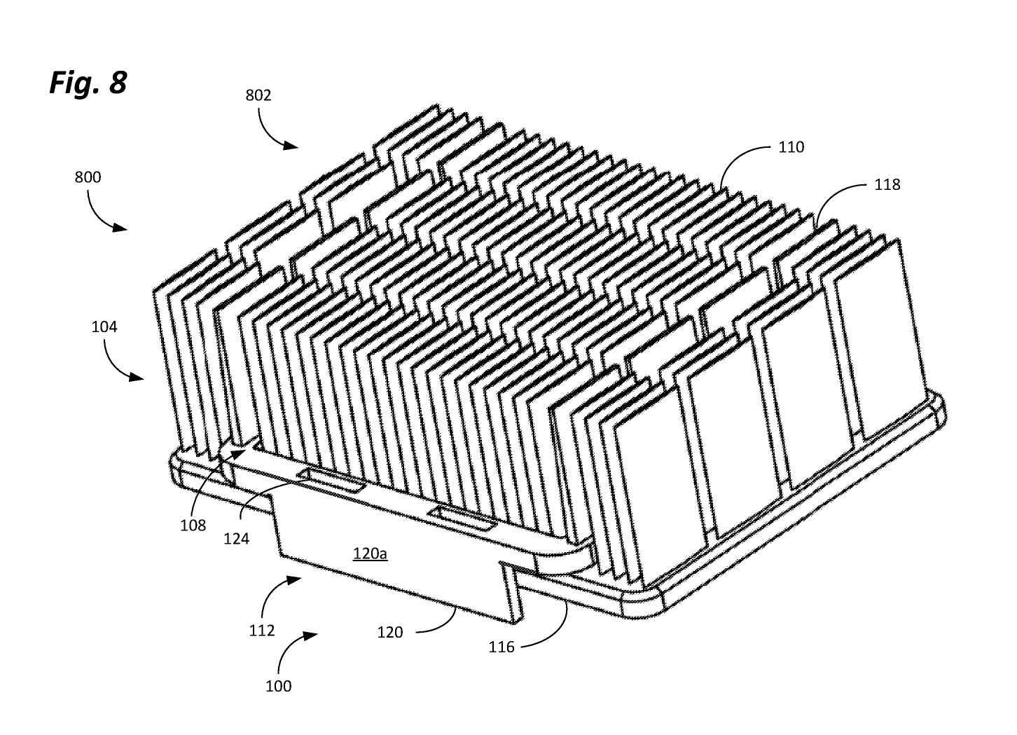

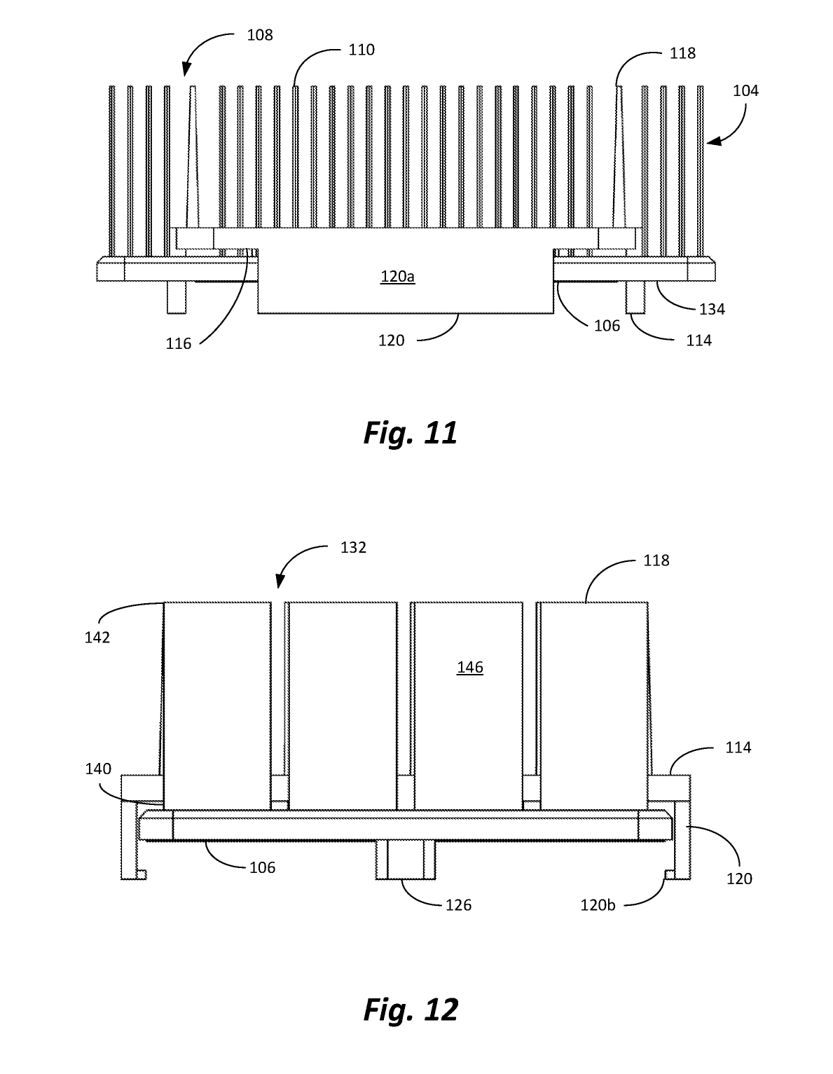

As shown in FIGS. 8-12, the retainer 100 and the heat sink 104 can form a cooling system 800. In the installed position, the retainer 100 can be disposed in between the rows 108 of heat sink cooling fins 110, such that the overall fin pattern 802 is substantially uniform. As discussed above, the retainer cooling fins 118 can be shaped to direct air over the frame 112 of the retainer 100, for example, or over specific portions of the heat sink 104 or IC 106.

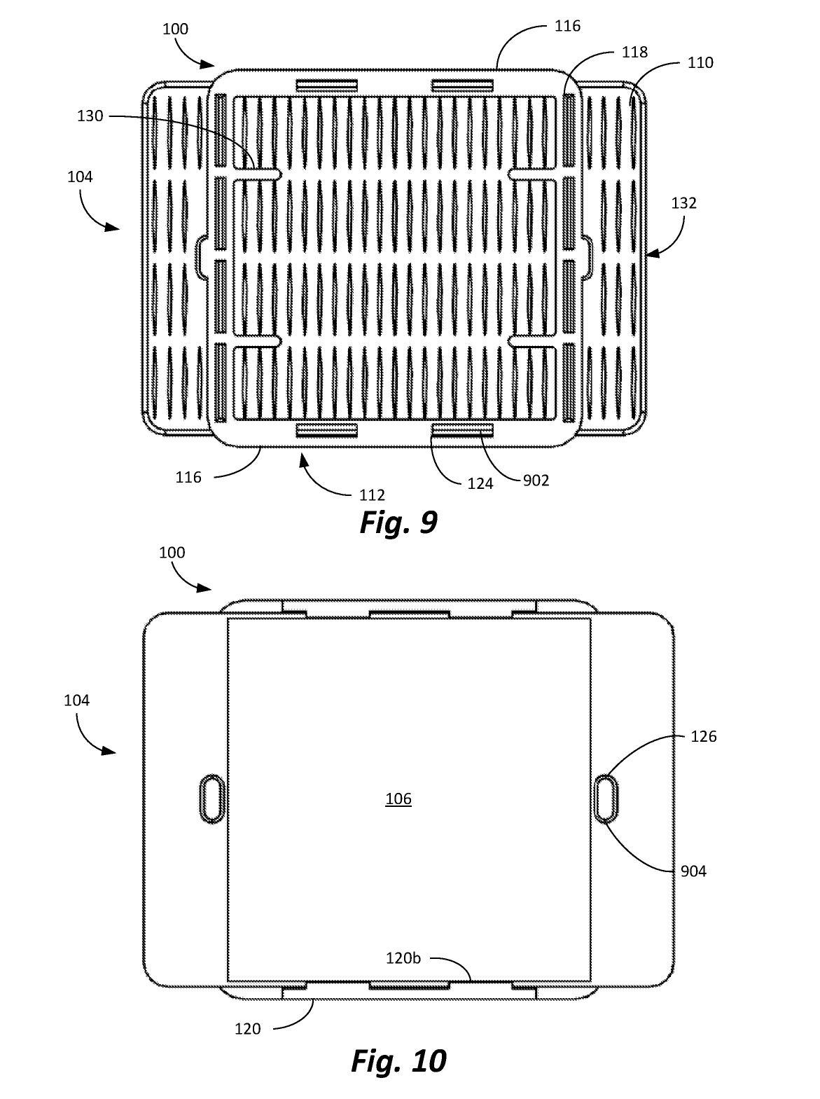

As shown in FIGS. 9-11, the slots 124 in the retainer can engage with tabs 902 on the heat sink 104 (or IC 106). In addition, the alignment pins 126 on the retainer 100 can engage with alignment holes or slots 904 on the heat sink 104 (or IC 106). Similarly, the hold downs 130 can apply downward pressure to the base 134 of the heat sink 104. As shown, in some examples, the hold downs 130 can be disposed in between the columns 132 of cooling fins 110, 118.

As shown in FIGS. 10 and 12, the tabs 120b of the clips 120 on the retainer 100 can engage with the IC 106 (or heat sink 104) to detachably couple the heat sink 104 to the IC 106. As mentioned above, the vertical walls 120a of the clips 120 on the retainer 100 can serve to align and contain the heat sink 104 and IC 106. In addition, in some examples, the retainer 100 can comprise a relatively resilient, or “springy,” material, to enable the retainer to snap on to the heat sink 104 and IC 106 and be held in place by the tabs 120b and friction.

As used herein the terms cooling, cooling capacity, heat rejection, heat rejection capacity, heat dissipation, heat dissipation efficiency, and like terms are used interchangeably. These terms are used to denote the general ability of a heat sink and/or retainer to maintain the temperature of an IC by absorbing and/or dissipating heat to, for example, the ambient air or liquid coolant. In addition, while the heat sinks discussed herein are shown as standard, finned heat sinks for ICs, examples of the present disclosure could also be used with other types of heat dissipation devices.

While several possible examples are disclosed above, examples of the present disclosure are not so limited. For instance, while systems and methods for use with ICs have been disclosed, the systems and methods could also be used with other electronic, electrical, electromechanical, or mechanical systems, for example, without departing from the spirit of the disclosure. In addition, while generally referred to above as a retainer for a heat sink in a computer or electronics setting, the system can be used to retain many types of mechanisms to increase their heat rejection capacity. Such changes are intended to be embraced within the scope of this disclosure.

The specific configurations, choice of materials, and the size and shape of various elements can be varied according to particular design specifications or constraints requiring a device, system, or method constructed according to the principles of this disclosure. Such changes are intended to be embraced within the scope of this disclosure. The presently disclosed examples, therefore, are considered in all respects to be illustrative and not restrictive. The scope of the disclosure is indicated by the appended claims, rather than the foregoing description, and all changes that come within the meaning and range of equivalents thereof are intended to be embraced therein.

1. A retainer for retaining a heat dissipating device on a heat source, the retainer comprising:
a substantially rectangular frame sized and shaped to retain the heat dissipating device on the heat source, the frame comprising:
two lateral rails disposed in a substantially parallel manner to each other; and
two longitudinal rails disposed in a substantially parallel manner to each other and substantially perpendicular to the two lateral rails; and
one or more retainer cooling fins location on at least one of the two lateral rails or the two longitudinal rails.

2. The retainer of claim 1, wherein at least one of the one or more retainer cooling fins is substantially wedge-shaped such that a base of the retainer cooling fin is wider than a tip of the retainer cooling fin.

3. The retainer of claim 2, wherein the base of the retainer cooling fin is substantially the same width as the lateral rail or longitudinal rail on which the retainer cooling fin is mounted.

4. The retainer of claim 1, wherein at least one of the one or more retainer cooling fins is substantially airfoil shaped such that a first side of the retainer cooling fin is longer than a second side of the retainer cooling fin, and wherein the retainer cooling fin generates lift in a first direction.

5. The retainer of claim 1, wherein at least one of the lateral rails, at least one of the longitudinal rails, or both comprise one or more slots sized and shaped to engage with one or more attachment or alignment devices on at least one of the heat dissipating device and the heat source.

6. The retainer of claim 1, wherein at least one of the lateral rails, at least one of the longitudinal rails, or both comprise one or more alignment pins sized and shaped to engage with one or more alignment holes on at least one of the heat dissipating device and the heat source.

7. The retainer of claim 1, wherein at least one of the lateral rails, at least one of the longitudinal rails, or both comprise one or more clips sized and shaped to engage with one or more portions of at least one of the heat dissipating device and the heat source, and wherein the one or more clips detachably couple the heat dissipating device to the heat source.

8. A system for cooling a heat source, the system comprising:
a heat dissipating device to dissipate heat from the heat source; and
a retainer to detachably couple the heat dissipating device to the heat source, the retainer comprising:
a substantially rectangular frame sized and shaped to retain the heat dissipating device on the heat source, the frame comprising:
two lateral rails disposed in a substantially parallel manner; and
two longitudinal rails disposed in a substantially parallel manner and substantially perpendicular to the two lateral rails; and
one or more retainer cooling fins location on at least one of the two lateral rails or the two longitudinal rails to dissipate heat from the heat source.

9. The system of claim 8, wherein the heat dissipating device comprises a heat sink, the heat sink comprising:
a based, with a first side and a second side, the first side in contact with at least a portion of a surface of the heat source; and
a plurality of heat sink cooling fins disposed on the second side to dissipate heat from the heat source.

10. The system of claim 9, wherein the plurality of heat sink cooling fins are disposed in a regular geometric pattern comprising rows and columns on the second side of the heat sink, and wherein the one or more retainer cooling fins are disposed on the retainer such that the one or more retainer cooling fins align with at least one of the rows and columns of the heat sink cooling fins.

11. The system of claim 9, wherein the plurality of heat sink cooling fins are disposed in a regular geometric pattern comprising rows and a predetermined number of columns on the second side of the heat sink;
wherein the one or more retainer cooling fins are disposed in the predetermined number of columns; and
wherein the one or more retainer cooling fins are disposed on the retainer such that the each of the one or more retainer cooling fins align with at least one column of the heat sink cooling fins.

12. The system of claim 11, the retainer further comprising:
a first set of one or more retainer cooling fins disposed on a first lateral rail of the two lateral rails; and
a second set of one or more retainer cooling fins disposed on a second lateral rail of the two lateral rails.

13. The system of claim 12, wherein the first lateral rail and the second lateral rail are each disposed between rows of heat sink cooling fins.

14. The system of claim 8, further comprising:
one or more hold downs disposed on at least one of the lateral rails and the longitudinal rails to maintain contact between the heat dissipating device and the heat source.

15. The system of claim 8, wherein the heat dissipating device is a heat sink; and
wherein the heat source is an integrated circuit chipset (IC).

16. The system of claim 8, wherein at least one of the one or more retainer cooling fins is substantially wedge-shaped such that a base of the retainer cooling fin is wider than a tip of the retainer cooling fin.

17. The system of claim 16, wherein the base is substantially the same width as the lateral rail or longitudinal rail on which it is mounted.

18. The system of claim 8, wherein at least one of the one or more retainer cooling fins is substantially airfoil shaped such that a first side of the retainer cooling fin is longer than a second side of the retainer cooling fin; and
wherein the retainer cooling fin generates lift in a first direction.

19. The system of claim 8, wherein at least one of the lateral rails, at least one of the longitudinal rails, or both comprise one or more clips sized and shaped to engage with one or more portions of the heat source;
wherein the one or more clips each comprise a vertical wall and a tab;
wherein each vertical wall substantially aligns the heat dissipating device to the heat source; and
wherein each tab detachably couples the heat dissipating device to the heat source.

20. The system of claim 8, further comprising:
a heat sink comprising a plurality of heat sink cooling fins; and
one or more hold downs disposed on at least one of the lateral rails and the longitudinal rails to maintain contact between the heat dissipating device and the heat source;
wherein the one or more hold downs are each disposed between a column of the one or more retainer cooling fins, the plurality of heat sink cooling fins, or both.
